(19) United States
(12) Patent Application Publication
(10) Pub. No.: US 2024/0268094 A1
(43) Pub. Date: Aug. 8, 2024

(54) SEMICONDUCTOR DEVICE HAVING STACKED CAPACITOR AND METHOD FOR FORMING THE SAME

(71) Applicant: Winbond Electronics Corp., Taichung City (TW)

(72) Inventor: Yen-Min RUAN, Taichung City (TW)

(21) Appl. No.: 18/435,505

(22) Filed: Feb. 7, 2024

(30) Foreign Application Priority Data
Feb. 7, 2023 (TW) 112104202

(51) Int. Cl. H10B 12/00

(52) U.S. Cl. CPC H10B 12/033; H10B 12/315

(57) ABSTRACT

A method for forming a semiconductor device includes forming a capacitor contact pad in an isolation layer. The method includes forming a first dielectric layer over the isolation layer. The method includes forming a recess in the first dielectric layer over the capacitor contact pad. The method includes conformally forming a protection layer in the recess. The method includes forming a second dielectric layer over the first dielectric layer. The method includes forming a trench through the isolation layer, the first dielectric layer, the protection layer, and the second dielectric layer to expose the capacitor contact pad. The method includes laterally etching the first dielectric layer and the second dielectric layer to enlarge the trench. The method includes conformally forming the bottom electrode layer of the stacked capacitor in the enlarged trench.

### CROSS REFERENCE TO RELATED APPLICATIONS

This application claims the benefit of Taiwan Patent Application No. 112104202 filed on Feb. 7, 2023, entitled “DYNAMIC RANDOM ACCESS MEMORY AND METHOD FOR FORMING THE SAME” which is hereby incorporated herein by reference.

### BACKGROUND OF THE INVENTION

### Field of the Invention

The present invention relates to a semiconductor device, and, in particular, to a semiconductor device having a stacked capacitor and method for forming the same.

### Description of the Related Art

The performance of a DRAM is positively correlated with the capacitance of the capacitor therein. As the size of integrated circuits decreases, the capacitance of the stacked capacitor of a DRAM may be increased by increasing the surface area of the bottom electrode layer. However, in current DRAM manufacturing, in the process of forming a trench for accommodating the stacked capacitor, the bottom of the ILD layer is further removed using wet etching to increase the surface area of the subsequently formed bottom electrode layer. However, if the conditions of the wet etching process are not well controlled, it may cause the neck portion of the ILD layer to be too narrow, and adjacent stacked capacitors may short-circuit.

### BRIEF SUMMARY OF THE INVENTION

This invention proposes a semiconductor device having a stacked capacitor and its formation method, which may solve the problem of adjacent stacked capacitors short-circuiting.

An embodiment of the present invention provides a method for forming a semiconductor device that includes forming a capacitor contact pad in an isolation layer. The method also includes forming a first dielectric layer over the isolation layer. The method also includes forming a recess in the first dielectric layer over the capacitor contact pad. The method also includes conformally forming a protection layer in the recess. The method also includes forming a second dielectric layer over the first dielectric layer. The method also includes forming a trench through the isolation layer, the first dielectric layer, the protection layer, and the second dielectric layer to expose the capacitor contact pad. The method also includes laterally etching the first dielectric layer and the second dielectric layer to enlarge the trench. The method also includes conformally forming the bottom electrode layer of a stacked capacitor in the enlarged trench.

An embodiment of the present invention provides a semiconductor device includes a capacitor contact pad disposed in an isolation layer. The semiconductor device also includes a first dielectric layer disposed over the isolation layer. The semiconductor device also includes a protection layer covering the top portion of the first dielectric layer. The semiconductor device also includes a second dielectric layer disposed over the protection layer. The semiconductor device also includes a bottom electrode layer that covers the first dielectric layer, the protection layer, and the second dielectric layer.

According to the semiconductor device and method for forming the same provided by the present disclosure, by forming a protection layer covering the top portion of the first dielectric layer of the stacked capacitor, the capacitance of the stacked capacitor may be increased, and adjacent stacked capacitors being short-circuited may be prevented when forming the stacked capacitor trench.

### BRIEF DESCRIPTION OF THE DRAWINGS

The present invention can be more fully understood by reading the subsequent detailed description and examples with references made to the accompanying drawings, wherein:

FIGS. 1A-1E are cross-sectional representations of various stages of forming a semiconductor memory structure in accordance with some embodiments.

FIG. 2 is a cross-sectional representation of a semiconductor memory structure in accordance with some other embodiments.

### DETAILED DESCRIPTION OF THE INVENTION

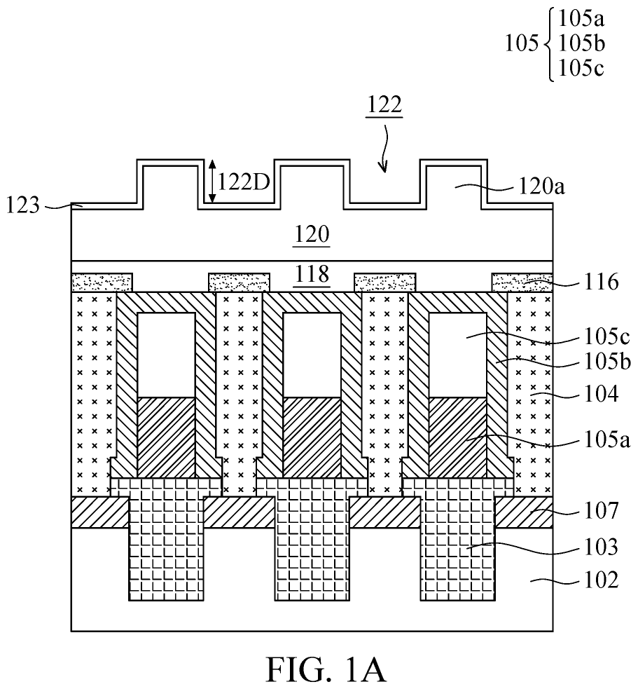

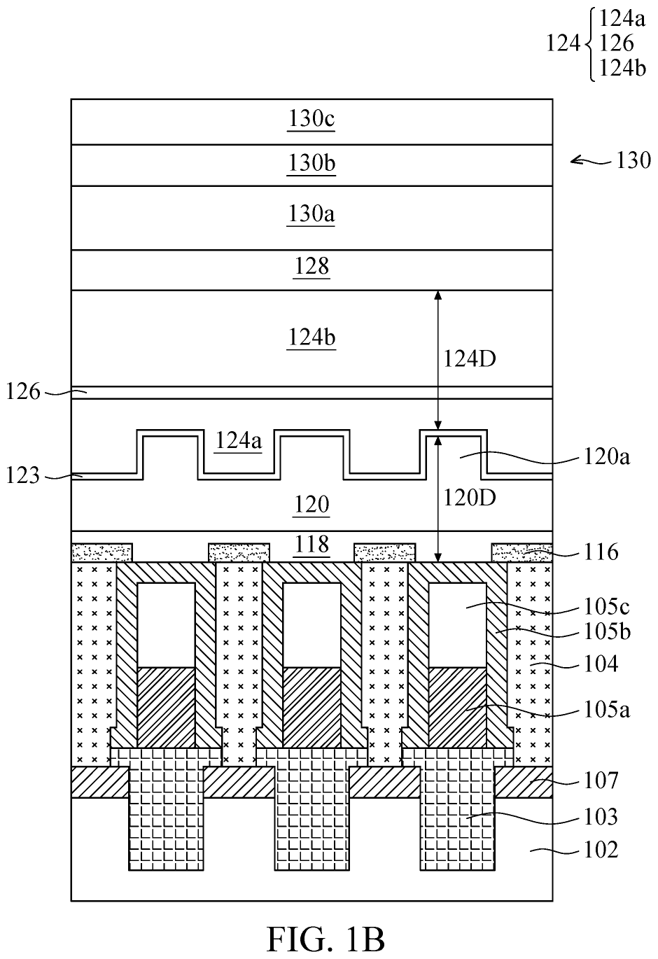

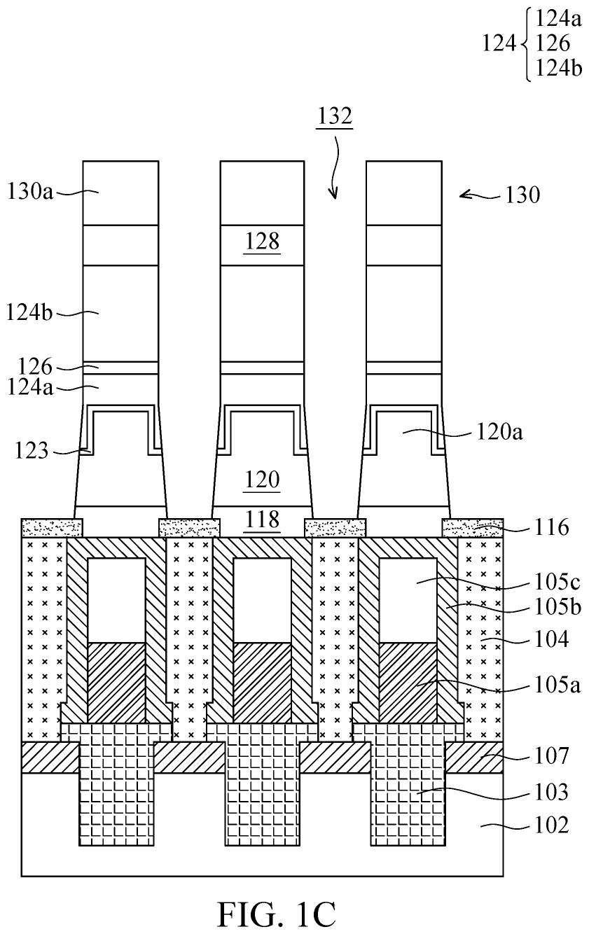

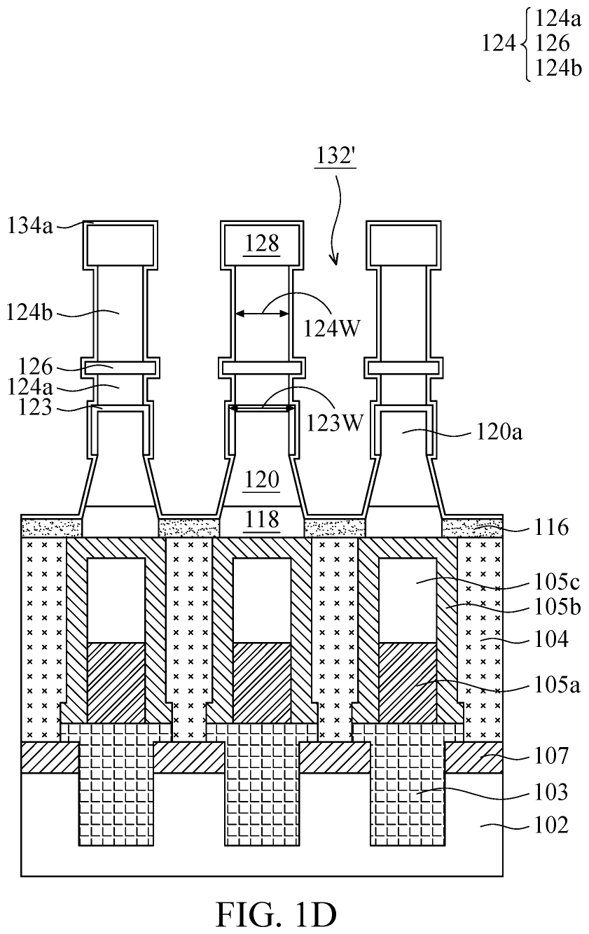

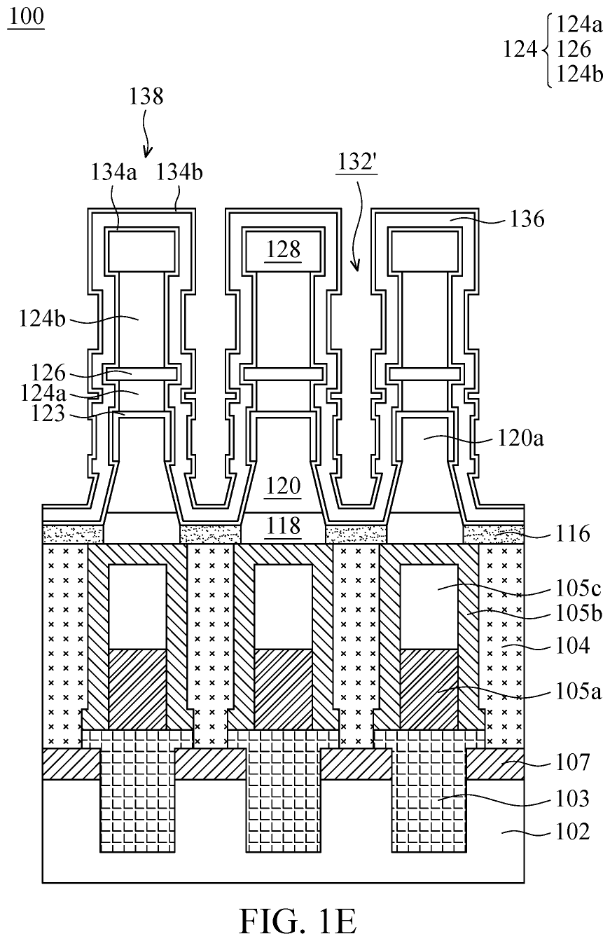

Please refer to FIG. 1A, a substrate 102 is provided. In some embodiments, an isolation structure 103, a buried word line structure (not shown), and a source/drain structure 107 may be formed in the substrate 102. Next, a contact structure 104 and a gate structure 105 is formed over the substrate 102. The material of the substrate 102 may include silicon, silicon containing semiconductors, silicon on insulator (SOI), other suitable semiconductor materials, or a combination thereof. In the present disclosure, the material of the substrate 102 is silicon. In some embodiments, the isolation structure 103 may include silicon oxide. The gate structure 105 may include a bit line 105a, a sidewall spacer 105b, and a capping layer 105c. The material of the bit line 105a may include for example, monocrystalline silicon, polysilicon, metal, alloy, other suitable conductive material, or a combination thereof. The material of the sidewall spacer 105b and the capping layer 105c may be a dielectric material. The contact structure 104 may include monocrystalline silicon, polysilicon, metal, alloy, or other suitable conductive material. The source/drain structure 107 may include P-type doped or N-type doped polysilicon. The buried word line structure, the isolation structure 103, the contact structure 104, the gate structure 105, and the source/drain structure 107 may be formed by any known process, and not repeated in herein. In the present disclosure, a planarization process may be performed if necessary, to make the top surface of the contact structure 104 level with the top surface of the gate structure 105.

Next, a capacitor contact pad 116 is formed over the contact structure 104. In an embodiment, before forming the capacitor contact pad 116, a sacrificial layer is formed covering the contact structure 104 and the gate structure 105 (not shown), and multiple openings corresponding to the positions of the capacitor contact pad 116 are formed in the sacrificial layer, and then a barrier layer is conformally formed in the openings (not shown) to prevent the conductive material in the capacitor contact pad 116 over the barrier layer diffusing in the underlying layer. The material of the barrier layer may include Ti, TiN, Ta, TaN, W, WN, other applicable material, or a combination thereof. The material of the capacitor contact pad 116 may include metal material (such as tungsten, aluminum, or copper), metal alloy, other suitable conductive material, or a combination thereof. The capacitor contact pad 116 may be formed by a deposition process, a sputtering process, or a combination thereof.

Next, an isolation layer 118 is formed over the capacitor contact pad 116. The isolation layer 118 may cover the top surface and the sidewalls of the capacitor contact pad 116, and the isolation layer 118 has a flat top surface. That is, the top surface of the capacitor contact pad 116 is lower than the top surface of the isolation layer 118. The isolation layer 118 may be SiN, SiCN, SiOC, SiOCN, other insulating material, or a combination thereof.

Next, a first dielectric layer 120 is formed over the isolation layer 118. In some embodiments, the first dielectric layer 120 may include borophosphosilicate glass (BPSG), un-doped silicate glass (USG), phosphosilicate glass (PSG). The isolation layer 118 and the first dielectric layer 120 may be formed by a deposition process, spin-coating process, or a combination thereof.

Next, a recess 122 is formed in the first dielectric layer 120 over the capacitor contact pad 116 by a patterning process such as a photolithography and an etching process, to make the first dielectric layer 120 has multiple protruding portions 120a. To increase the capacitance of the subsequently formed stacked capacitor, each protruding portion 120a may be not within the vertical projection area of the capacitor contact pad 116. Besides, in some embodiments, in order to make the stacked capacitor has better capacitance, and provide better protection for the stacked capacitor, the depth 122D of the recess 122 may be 10% to 40% of the thickness of the first dielectric layer 120. The patterning process may include photoresist coating (e.g., spin-on coating), soft baking, mask aligning, exposure, post-exposure baking, developing the photoresist, rinsing and drying (e.g., hard baking), other suitable techniques, or a combination thereof. The etching process may include a dry etching process or a wet etching process.

Next, a protection layer 123 is conformally formed over the first dielectric layer 120 having the recess 122. The protection layer 123 may include nitrides such as SiN, SiCN, SiOCN, polysilicon, or a combination thereof. In some embodiments, in order to enhance the subsequently etching process window, and to decrease the probability of abnormal profile of subsequently formed stacked capacitor, and further decrease the probability of adjacent stacked capacitors being short-circuited, the thickness of the protection layer 123 may be 10% to 30% of the depth 122D of the recess 122, for example, around 20 nm to around 30 nm. The protection layer 123 may be formed by the deposition process, such as the ALD process.

Next, as shown in FIG. 1B, a second dielectric layer 124 is formed over the protection layer 123 filling up the recess 122. In some embodiments, the first dielectric layer 120 and the second dielectric layer 124 are made of different materials with different etching rate. In some embodiments, in the etching process of forming the trench 132 (132′), the etching rate of the first dielectric layer 120 is greater the etching rate of the second dielectric layer 124. The second dielectric layer 124 may include silane (SiH₄). In some embodiments, the maximum thickness 120D of the first dielectric layer 120 and the maximum thickness 124D of the second dielectric layer 124 are substantially the same.

In some embodiments, a supporting layer 126 is optionally formed in the second dielectric layer 124. The supporting layer 126 may be used to support subsequently formed stacked capacitor. When the protection layer 123 is made of dielectric material, the material of the supporting layer 126 may be the same as the material of the protection layer 123. The supporting layer 126 may include SiN, SiCN, SiOC, SiOCN, other applicable dielectric materials, or a combination thereof. The first portion 124a of the second dielectric layer 124 may be formed in the recess 122 first, and then the supporting layer 126 may be formed over the first portion 124a, and the second portion 124b of the second dielectric layer 124 may be formed over the supporting layer 126. The first portion 124a of the second dielectric layer 124 may be used to recover the damage of underlying films.

Next, a capping layer 128 is formed over the second dielectric layer 124. The capping layer 128 may include SiN, SiCN, SiOC, SiOCN, other applicable dielectric materials, or a combination thereof. The second dielectric layer 124, the supporting layer 126, and the capping layer 128 may be formed by the deposition process, the spin-coating process, or a combination thereof.

Next, a hard mask layer 130 is formed over the capping layer 128. The hard mask layer 130 may include the first hard mask layer 130a, the second hard mask layer 130b, and the third hard mask layer 130c. The second hard mask layer 130b is formed over the first hard mask layer 130a, and the third hard mask layer 130c is formed over the second hard mask layer 130b. The first hard mask layer 130a may include polysilicon. The second hard mask layer 130b may include tetraethyl orthosilicate (TEOS). The third hard mask layer 130c may include carbon-containing material. The hard mask layer 130 may be formed by a deposition process, a spin-coating process, or a combination thereof. It should be noted that, the hard mask layer 130 may be formed including different materials and different layer numbers, depending on the process demands, and the present disclosure is not limited thereto.

Next, as shown in FIG. 1C, a trench 132 is formed through the hard mask layer 130, the second dielectric layer 124, the protection layer 123, the first dielectric layer 120, and the isolation layer 118 to expose the capacitor contact pad 116 by a patterning process such as a lithography and an etching process. In some embodiments, after forming the trench 132, remaining second dielectric layer 124 is still formed over the sidewalls of the protection layer 123. The etching process may include a dry etching process (such as anisotropic plasma etching, reactive ion etching, or a combination thereof.) The second hard mask layer 130b and the third hard mask layer 130c are removed when forming the trench 132.

Next, as shown in FIG. 1D, an etching process is performed to laterally etching the first dielectric layer 120 and the second dielectric layer 124 to enlarge the trench 132 as a stacked capacitor trench 132′. After the etching process, the sidewall of the supporting layer 126 laterally protrudes from the sidewall of the second dielectric layer 124, and the sidewall of the protection layer 123 is exposed. The protection layer 123 may prevent the first dielectric layer 120 from being over-etched, thereby may protect the protruding portion 120a of the first dielectric layer 120, and further prevent the subsequently formed stacked capacitors 138 from being short-circuited. In some embodiments, the sidewalls of the protection layer 123 are vertical. After the etching process, the maximum width 123W of the protection layer 123 is greater than the minimum width 124W of the second dielectric layer 124. After the etching process, the sidewalls of the lower portion of the first dielectric layer 120 are inclined, and the width of the bottom surface of the first dielectric layer 120 is greater than the width of the top surface. In some embodiments, the top portion of the first dielectric layer 120 (i.e., the protruding portion 120a) has the minimum width of the first dielectric layer 120. In some embodiments, the protection layer 123 covers the top portion of the first dielectric layer 120. In some embodiments, the etching process includes using dilute hydrofluoric acid. In the etching process, the supporting layer 126 and the second dielectric layer 124 have etching selectivity. In the etching process, the first hard mask layer 130a is removed. In some embodiments, after the etching process, the top surface of the capacitor contact pad 116 is entirely exposed, namely not covered by the isolation layer 118.

Next, the bottom electrode layer 134a of the stacked capacitor 138 is conformally formed in the stacked capacitor trench 132′. The bottom electrode layer 134a may cover the sidewalls of the isolation layer 118, the first dielectric layer 120, the protection layer 123, the second dielectric layer 124, the capping layer 128, and the top surfaces of the capping layer 128 and the capacitor contact pad 116. The bottom electrode layer 134a also covers the sidewalls and the top and bottom surfaces of the protruding portion of the supporting layer 126. The bottom electrode layer 134a may include TiN, TaN, TiAlN, TiW, WN, Ti, Au, Ta, Ag, Cu, AlCu, Pt, W, Ru, Al, Ni, metal nitrides, other suitable electrode material, or a combination thereof.

Next, as shown in FIG. 1E, the dielectric layer 136 of the stacked capacitor 138 is conformally formed over the bottom electrode layer 134a, the dielectric layer 136 may include a dielectric material with a high dielectric constant, such as HfO2, LaO, AlO, ZrO, TiO, Ta₂O₅, Y₂O₃, SrTiO₃, BaTiO₃, BaZrO, HfZrO, HfLaO, HfTaO, HfSiO, HfSiON, fTiO, LaSiO, AlSiO, Al₂O₃ , or a combination thereof. The bottom electrode layer 134a and the dielectric layer 136 may be formed by a deposition process, a spin-on coating process, a sputtering process, or a combination thereof.

Next, the top electrode layer 134b of the stacked capacitor 138 is conformally formed over the dielectric layer 136. The processes and materials for forming the top electrode layer 134b may be the same as, or similar to, those used to form the bottom electrode layer 134a. The descriptions of these processes and materials are not repeated herein. Besides, some well-known structures and processes for manufacturing a DRAM 100 may be adopted to complete the DRAM 100, but are omitted here to simplify the description. In addition, the present invention is not limited to form a DRAM, and can be used to form any semiconductor device having a stacked capacitor.

As mentioned above, by forming a protection layer 123 covering the top portion of the first dielectric layer 120 may prevent subsequently formed stacked capacitors 138 from being short-circuited. The stacked capacitor trench 132′ formed according to the present disclosure, the top portion of the first dielectric layer 120 may have a minimum width of the first dielectric layer 120, thereby the capacitance of the stacked capacitor 138 may be increased. In addition, the supporting layer 126 formed in the second dielectric layer 124 may also provide more support to the stacked capacitor 138, and thereby increase the yield of the DRAM 100.

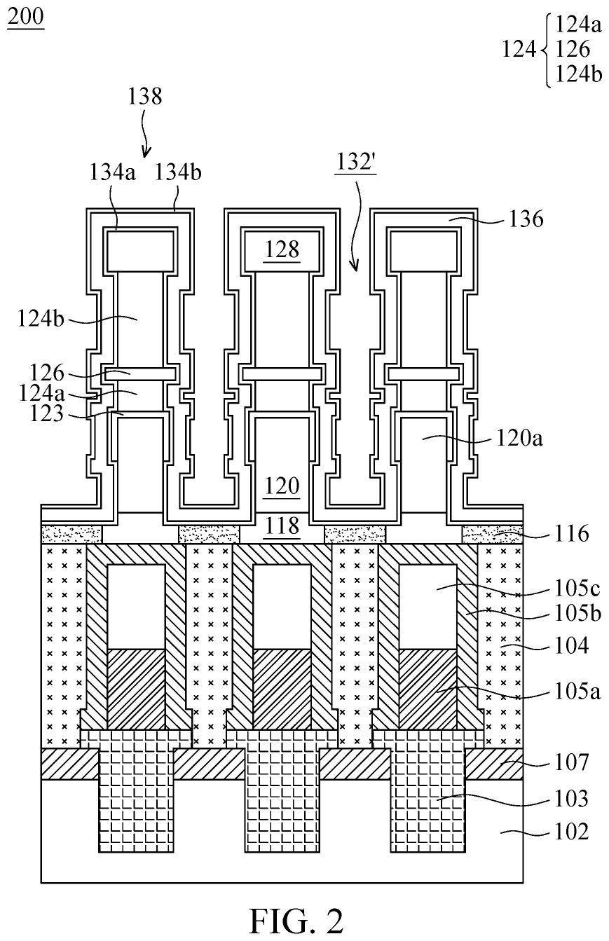

FIG. 2 is a cross-sectional representation of a semiconductor device structure 200. Some processes or devices are the same as, or similar to, those described in the embodiments above, and therefore the descriptions of these processes and devices are not repeated herein. The difference from the embodiments described above is that, as shown in FIG. 2 the sidewalls of the lower portion of the first dielectric layer 120 are vertical.

When enlarging the trench 132 by the etching process, the concentration and the action time of etchant such as dilute hydrofluoric acid may be modified, in order to modify the profile of the stacked capacitor trench 132′. For example, the sidewalls of the lower portion of the first dielectric layer 120 are vertical. In this way, the contact area of the stacked capacitor 138 is further increased, and the capacitance of the stacked capacitor 138 is further increased.

As mentioned above, by forming a protection layer including nitrides or polysilicon at the middle portion of the sidewall of the stacked capacitor, the top portion with minimum width of the first dielectric layer are prevent from being damaged when forming the stacked capacitor trench, and adjacent stacked capacitors are prevented from merging. Meanwhile, the capacitance of the stacked capacitor may be increased. A supporting layer may be in the dielectric layer between the stacked capacitors, which may also help to maintain the profile of the stacked capacitor trench. In addition, when forming the stacked capacitor trench, the concentration and the action time of etchant such as dilute hydrofluoric acid may be modified, in order to modify the profile of the trench, which may further increase the capacitance of the stacked capacitor.

The present invention is suitable for making miniaturized stacked capacitor, so as to increase the total number of dies on a wafer. Therefore, the production cost and energy consumption of manufacturing a single IC are reduced, and the production energy consumption of subsequent packaging is also reduced, thereby reducing carbon emissions in the process of producing a semiconductor device having stacked capacitors. Besides, since reliability and durability of the semiconductor device of the present invention are improved, the present invention provides a sustainable semiconductor device.

Accordingly, the present disclosure may be used on automotive electronics, such as electronic vehicle, Advanced Driver Assistance Systems (ADAS), Instrument Clusters, Infotainment. The present disclosure may be used on Industrial applications, such as aerospace, medical, safety equipment, health & fitness, industrial controls, instrumentation, security, transportation, telecommunications, PoS machines, human machine interface, programmable logic controller, smart meter, and industrial networking. The present disclosure may be used on communication and networking devices such as STB, switches, routers, passive optical networks, xDSL, wireless access point, cable modem, power line communications M2M, mobile phones, base stations, DECT phones, and many other new communication products. The present disclosure may be used on desktops, notebooks, servers, gaming notebooks, ultrabooks, tablets, convertibles, HDD, and SSD. The present disclosure may be used on space constrained applications including Wearable, MP3 players, smart watches, games, digital radio, toys, cameras, digital photo album, GPS, Bluetooth and WiFi modules. The present disclosure may be used on television, display and home electronics.

What is claimed is:

1. A method for forming a semiconductor device, comprising:
forming a capacitor contact pad in an isolation layer;
forming a first dielectric layer over the isolation layer;
forming a recess in the first dielectric layer over the capacitor contact pad;
conformally forming a protection layer in the recess;
forming a second dielectric layer over the first dielectric layer;
forming a trench through the isolation layer, the first dielectric layer, the protection layer, and the second dielectric layer to expose the capacitor contact pad;
laterally etching the first dielectric layer and the second dielectric layer to enlarge the trench; and
conformally forming a bottom electrode layer of a stacked capacitor in the enlarged trench.

2. The method for forming the semiconductor device as claimed in claim 1, wherein a sidewall of the protection layer is exposed after laterally etching the first dielectric layer and the second dielectric layer.

3. The method for forming the semiconductor device as claimed in claim 1, further comprising:
forming a capping layer over the second dielectric layer;
forming a hard mask layer over the capping layer; and
forming a supporting layer in the second dielectric layer.

4. The method for forming the semiconductor device as claimed in claim 3, wherein a sidewall of the supporting layer protrudes from a sidewall of the second dielectric layer after laterally etching the first dielectric layer and the second dielectric layer.

5. The method for forming the semiconductor device as claimed in claim 1, wherein the first dielectric layer and the second dielectric layer are laterally etched by dilute hydrofluoric acid.

6. The method for forming the semiconductor device as claimed in claim 1, further comprising:
conformally forming a third dielectric layer of the stacked capacitor over the bottom electrode layer; and
forming a top electrode layer of the stacked capacitor over the third dielectric layer.

7. The method for forming the semiconductor device as claimed in claim 1, wherein the protection layer and the second dielectric layer have an etching selectivity.

8. The method for forming the semiconductor device as claimed in claim 1, wherein the protection layer comprises nitrides or polysilicon.

9. The method for forming the semiconductor device as claimed in claim 3, wherein the hard mask layer comprises a first hard mask layer and a second hard mask layer, and the second hard mask layer is formed over the first hard mask layer, and the formation method further comprises:
removing the second hard mask layer when forming the trench; and
removing the first hard mask layer when laterally etching the first dielectric layer and the second dielectric layer.

10. A semiconductor device, comprising:
a capacitor contact pad disposed in an isolation layer;
a first dielectric layer disposed over the isolation layer;
a protection layer covering a top portion of the first dielectric layer;
a second dielectric layer disposed over the protection layer; and
a bottom electrode layer covering the first dielectric layer, the protection layer, and the second dielectric layer.

11. The semiconductor device as claimed in claim 10, further comprising:
a capping layer disposed over the second dielectric layer;
a supporting layer disposed in the second dielectric layer,
wherein the supporting layer laterally protrudes from the second dielectric layer, and the bottom electrode layer covers a sidewall of the capping layer and a top surface of the capping layer.

12. The semiconductor device as claimed in claim 11, wherein the protection layer and the supporting layer are made of a same dielectric material.

13. The semiconductor device as claimed in claim 10, wherein a lower portion of the first dielectric layer has a vertical sidewall.

14. The semiconductor device as claimed in claim 10, wherein a top surface of the capacitor contact pad is lower than a top surface of the isolation layer.

15. The semiconductor device as claimed in claim 10, wherein a maximum thickness of the first dielectric layer is equal to a maximum thickness of the second dielectric layer.

16. The semiconductor device as claimed in claim 10, wherein the protection layer covers a top portion of the first dielectric layer.

17. The semiconductor device as claimed in claim 10, wherein a maximum width of the protection layer is greater than a minimum width of the second dielectric layer.

18. The semiconductor device as claimed in claim 10, wherein a width of a bottom surface of the first dielectric layer is greater than a width of a top surface of the first dielectric layer.

19. The semiconductor device as claimed in claim 10, wherein a sidewall of the protection layer is vertical.

20. The semiconductor device as claimed in claim 10, wherein the first dielectric layer is not within the vertical projection area of the capacitor contact pad.
